(19) United States
(12) Patent Application Publication
(10) Pub. No.: US 2006/0148123 A1
(43) Pub. Date: Jul. 6, 2006

(54) Method for fabricating CMOS image sensor

(76) Inventor: Jin Han Kim, Icheon-city (KR)

Correspondence Address: MCKENNA LONG & ALDRIDGE LLP;Song K. Jung, 1900 K Street, N. W., Washington, DC, 20006, US

(21) Appl. No.: 11/320,904

(22) Filed: Dec. 30, 2005

(30) Foreign Application Priority Data
Dec. 31, 2004 (KR) 2004-0117959

(51) Int. Cl. H01L 21/00

(52) U.S. Cl. 438/69; 438/70

(57) ABSTRACT

A method for fabricating a CMOS image sensor includes forming a metal pad on a pad region of a semiconductor substrate having an active region and the pad region, forming an insulating film on an entire surface of the semiconductor substrate including the metal pad, forming an opening to expose the metal pad by etching a portion of the insulating film corresponding to the metal pad, forming a pad passivation film on the insulating film including the opening, forming color filter layers on a portion of the pad passivation film corresponding to the active region, removing a portion of the pad passivation film corresponding to the pad region, and forming microlenses over the color filter layers after removing the portion of the pad passivation film corresponding to the pad region.

### CROSS-REFERENCE TO RELATED APPLICATION

This application claims the benefit of Korean Patent Application No. P2004-117959, filed on Dec. 31, 2004, which is hereby incorporated by reference for all purposes as if fully set forth herein.

### BACKGROUND OF THE INVENTION

1. Field of the Invention

The present invention relates to a method for fabricating a complementary metal-oxide semiconductor (CMOS) image sensor, and more particularly, to a method for fabricating a CMOS image sensor, in which a pad passivation film is thickly formed and is removed before microlenses are formed, so as to prevent a defect in the microlenses from occurring and to obtain white uniformity, thereby improving quality and yield of the image sensor.

2. Discussion of the Related Art

Generally, an image sensor is a semiconductor device that converts optical images to electrical signals. The image sensor is classified into a charge coupled device (CCD) or a CMOS image sensor. The CCD stores charge carriers in MOS capacitors and transfers the charge carriers to the MOS capacitors. The MOS capacitors are adjacent to one another. The CMOS image sensor employs a switching mode that sequentially detects outputs of unit pixels using MOS transistors by forming the MOS transistors that correspond to the number of the unit pixels using CMOS technology that uses a control circuit and a signal processing circuit as peripheral circuits.

The CMOS image sensor that converts light signals into electrical signals includes signal processing chips having photodiodes. Each of the signal processing chips includes an amplifier, an analog-to-digital converter (A/D converter), an internal voltage generator, a timing generator, and digital logic. It is economical in view of space, power consumption, and cost. The manufacture of the CCD requires technical process steps. However, the CMOS image sensor can be manufactured by mass production with a simple etching process of a silicon wafer cheaper than that of the CCD. Also, the CMOS image sensor has an advantage with respect to packing density.

To enhance light sensitivity of the CMOS image sensor, the fill factor can be increased, which is the area occupied by a photodiode relative to the whole area of the image sensor. However, such efforts have had limited success because of the area that is taken up by the logic circuit for signal processing. Therefore, it is necessary to change a path of incident light to an area other than the photodiode so as to condense the incident light to the photodiode. To condense the incident light to the photodiode, a microlens is generally used.

The CMOS image sensor is widely used for various application fields such as digital cameras, mobile communication terminals, video phones, and computer cameras. The CMOS image sensor is fabricated by processes for forming color filter layers and microlenses after the processes of forming a metal pad and a device isolation film. These processes can be essential to the yield and other characteristics of the image sensor.

After a metal pad of the image sensor is opened, color filter layers and a planarization layer are formed by photo processes. At this time, if no process for protecting the metal pad is performed, the opened metal pad may react with a developer. As a result, a fluorine ion in the developer may corrode the metal pad and cause metal contamination to impede soft probing during a probe test. If a probe test is performed by hard probing, many metal particles may be generated. Thus, the yield of a wafer level is deteriorated by function failure, and yield of a package level is also deteriorated by a defect of wire bonding.

Various processes for protecting the metal pad from the photo processes have been developed. One of the processes is a process of removing a plasma enhanced (PE) TEOS film after respectively forming color filter layers and microlenses in which the PE TEOS film is thinly deposited on an opened metal pad before the color filter layers are formed. In this case, the PE TEOS film is used as a pad passivation film. The PE TEOS film is used to minimize physical plasma damage of the microlenses when the PE TEOS film is etched, thereby minimizing a defect of the microlenses.

In more detail, since the photo processes are usually not performed after the metal pad is opened, the PE TEOS film on the metal pad is removed after the last photo process. However, when the PE TEOS film is removed, the microlenses may be deformed or image uniformity may be deteriorated. This drawback becomes serious as the PE TEOS film becomes thicker. By contrast, if the PE TEOS film is too thin, thickness uniformity is deteriorated to adversely affect white uniformity during an optical test of the image sensor. The white uniformity represents an image level difference between a center pixel block and an edge pixel block.

Hereinafter, a conventional method for fabricating a CMOS image sensor will be described with reference to the accompanying drawings.

FIG. 1 to FIG. 4 are sectional views illustrating a CMOS image sensor being fabricated after a metal pad is formed in accordance with a conventional method.

Referring to FIG. 1, a metal pad 10 is formed on an interlayer insulating film (not shown). An oxide film 12 used as a device passivation film is deposited on the interlayer insulating film, including the metal pad 10. The oxide film 12 is then planarized by a chemical mechanical polishing (CMP) process. A nitride film 14 used as a device passivatin film is deposited on the oxide film 12. A photoresist film (not shown) is coated on the nitride film 14 and then patterned by exposing and developing processes to form a photoresist pattern (not shown) that opens the metal pad 10. The oxide film 12 and the nitride film 14 are etched using the photoresist pattern as a mask to expose the metal pad 10.

As shown in FIG. 2, a PE TEOS film serving as a pad passivation film 16 is deposited on an entire surface of a semiconductor substrate so as to prevent the opened metal pad 10 from being contaminated during a process of forming red, green and blue color filter arrays, a planarization process, and a process of forming microlenses. At this time, the pad passivation film 16 should not exceed 500 Å, and a thermal curing process is performed to remove fluorine ions from the metal pad.

As shown in FIG. 3, red, green and blue color filter array layers 18 are formed on the pad passivation film 16, and a planarization layer 20 is formed on the pad passivation film 16, including the color filter array layers 18. Microlenses 22 are formed on the planarization layer 20. A thermal reflow process such as bleach is performed when the microlenses 22 are formed.

As shown in FIG. 4, the pad passivation film 16 on a pad region is removed by a plasma dry etching process. The microlenses 22 formed according to this method have relatively poor characteristics compared to those formed without using a plasma dry etching process.

In the conventional CMOS image sensor fabricated as above, the pad passivation film 16 formed after the process of forming the device passivation films 12 and 14 is thin so as to degrade uniformity of the device and adversely affect white uniformity of the image sensor. A defect such as lens shading occurs in the microlenses 22 due to the etching process of the pad passivation film 16 performed after the process of forming the microlenses. Also, white uniformity is degraded to deteriorate the yield and quality of the image sensor.

The white uniformity is obtained by comparing a minimum value with a maximum value in color signals between a center pixel block and an edge pixel block. Since the white uniformity is susceptible to defects of the microlenses 22 or variation of the layers below the microlenses, its characteristics may be degraded if the pad passivation film 16 below the color filter array layers has relatively poor uniformity. Particularly, a white uniformity failure rate is increased by the microlenses 22 having a defect when the pad passivation film 16 is removed after the microlenses 22 are formed. For this reason, the yield of the image sensor and its quality can be simultaneously deteriorated.

The conventional method for fabricating the aforementioned CMOS image sensor has at least the following problems.

The pad passivation film formed after the process of forming the device passivation films is thin so as to degrade the uniformity of the device and adversely affect the white uniformity of the image sensor. Also, since the pad passivation film is etched after the microlenses are formed, a defect such as lens shading occurs in the microlenses and white uniformity is degraded.

### SUMMARY OF THE INVENTION

Accordingly, the present invention is directed to a method for fabricating a CMOS image sensor, which substantially obviates one or more problems due to limitations and disadvantages of the related art.

The present invention provides a method for fabricating a CMOS image sensor, in which a pad passivation film is thickly formed and removed before microlenses are formed, so as to prevent defects in the microlenses from occurring and to obtain white uniformity, thereby improving quality and yield of the image sensor.

Additional advantages and features of the invention will be set forth in the description which follows and will become apparent to those having ordinary skill in the art upon examination of the following. These and other advantages of the invention may be realized and attained by the structure particularly pointed out in the written description and claims hereof as well as the appended drawings.

To achieve these and other advantages and in accordance with the invention, as embodied and broadly described herein, a method for fabricating a CMOS image sensor according to the present invention includes forming a metal pad on a pad region of a semiconductor substrate having an active region and the pad region; forming an insulating film on an entire surface of the semiconductor substrate, including the metal pad; forming an opening to expose the metal pad by etching a portion of the insulating film corresponding to the metal pad; forming a pad passivation film on the insulating film including, the opening; forming color filter layers on a portion of the pad passivation film corresponding to the active region; removing a portion of the pad passivation film corresponding to the pad region; and forming microlenses over the color filter layers after removing the portion of the pad passivation film corresponding to the pad region.

The method can further include forming a planarization layer between the color filter layers and the microlenses.

The pad passivation film can be formed at a thickness of 800 Å to 1200 Å.

The insulating film can include an oxide film and a nitride film on the oxide film.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention, illustrate exemplary embodiments of the invention and together with the description serve to explain the principle of the invention. In the drawings:

FIG. 1 to FIG. 4 are sectional views illustrating a CMOS image sensor manufactured in accordance with a conventional method; and

FIG. 5 to FIG. 9 are sectional views illustrating a CMOS image sensor fabricated in accordance with an exemplary embodiment of the present invention.

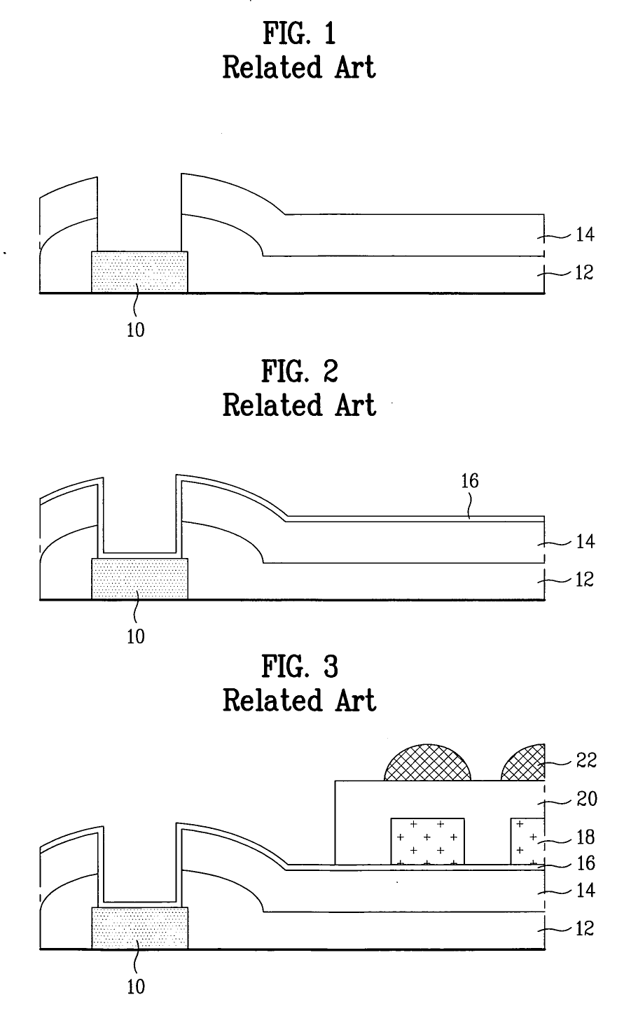

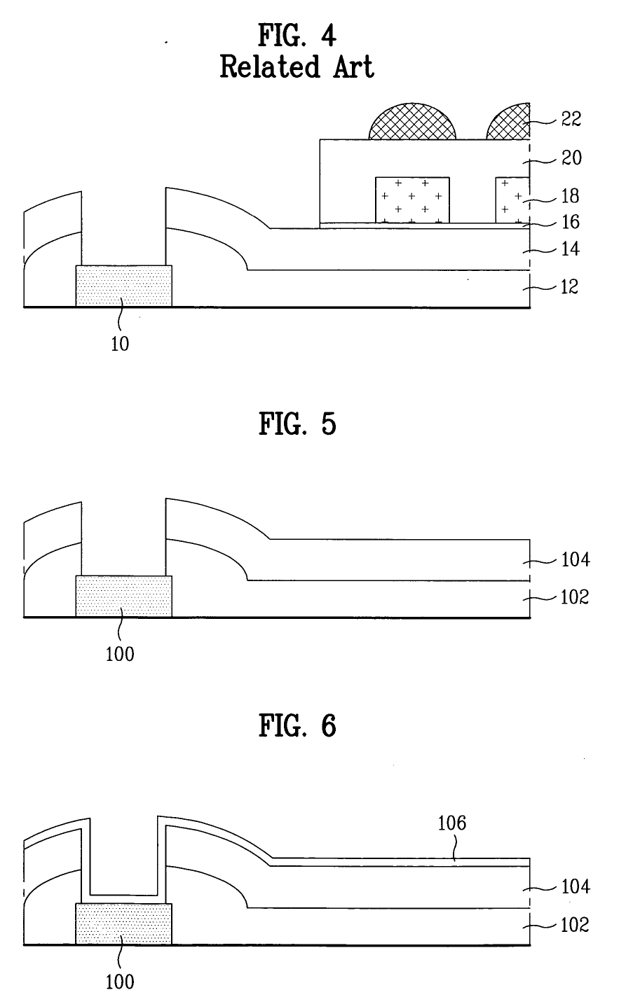

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

FIG. 5 to FIG. 9 are sectional views illustrating a method for fabricating a CMOS image sensor according to an exemplary embodiment of the present invention.

First, a process of forming a metal pad will be briefly described. A first epitaxial layer is grown on a semiconductor substrate, and a red photodiode is formed in the first epitaxial layer. Then, a second epitaxial layer is grown on the first epitaxial layer, including the red photodiode, and a green photodiode is formed in the second epitaxial layer. A third epitaxial layer is grown on the second epitaxial layer, including the green photodiode, and a blue photodiode is formed in the third epitaxial layer. Also, a trench is formed in the third epitaxial layer to insulate the fields from each other. The trench is filled with an insulating material to form a shallow trench isolation (STI). A first interlayer insulating film is deposited on the third epitaxial layer, and a first metal layer is formed on the first interlayer insulating film. The first metal layer is then patterned to form a first metal line. The processes of forming the first interlayer insulating film and the first metal line are repeated several times to deposit the desired number of metal lines. A second interlayer insulating film is deposited on the final first interlayer insulating film, and a final metal layer is formed on the second interlayer insulating film. The final metal layer is then patterned to form a final metal line and a metal pad.

As shown in FIG. 5, an oxide film 102 used as a device passivation film is deposited on the second interlayer insulating film (not shown) including the metal pad 100. The oxide film 102 is then planarized by a chemical mechanical polishing (CMP) process. A nitride film 104 used as a device passivation film is deposited on the oxide film 102. Undoped silica glass high density plasma (USG HDP) can be used as the oxide film 102, and PECVD SiN can be used as the nitride film 104.

Subsequently, a photoresist film (not shown) is coated on the nitride film 104 and then patterned by exposing and developing processes to form a photoresist pattern (not shown) that opens a region for the metal pad 100. The oxide film 102 and the nitride film 104 are etched using the photoresist pattern as a mask to expose the metal pad 100.

As shown in FIG. 6, a PE TEOS film 106 serving as a pad passivation film is deposited so as to prevent the opened metal pad 100 from being contaminated during a process of forming red, green and blue color filter arrays, a planarization process, and a process of forming microlenses. At this time, the PE TEOS film 106 has a deposition thickness of 800 Å to 1200 Å, which generally corresponds to about two times the PE TEOS film utilized in the related art. Uniformity of the device is improved by such a deposition thickness. Also, a thermal curing process is performed to remove a fluorine ion on the metal pad 100.

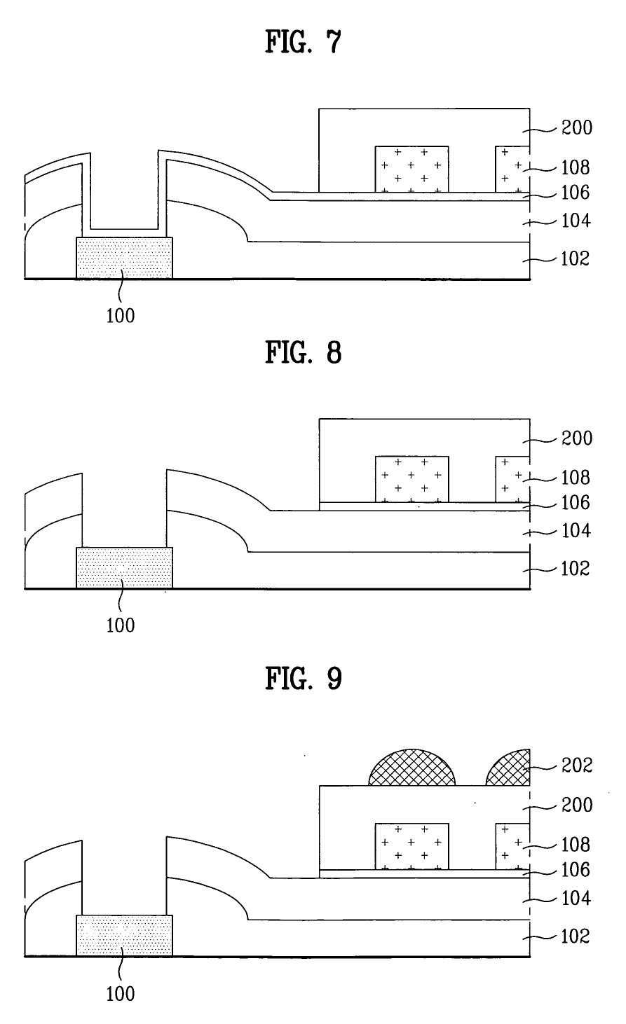

As shown in FIG. 7, red, green and blue color filter array layers 108 are formed on the PE TEOS film 106, and a planarization layer 200 is formed on the pad passivation film 106, including the color filter array layers 108. In this case, a photoresist film used as the planarization layer 200 is coated with an increased thickness of about 0.1 μm to 0.2 μm relative to the thickness of the related art.

As shown in FIG. 8, a region having no planarization layer, i.e., the PE TEOS film 106 on the pad region, is removed by a plasma dry etching process. The planarization layer 200 may be slightly damaged when the PE TEOS film 106 is removed. However, since the planarization layer 200 is thickly formed, the damage of the planarization layer is smaller than that of microlenses. Therefore, the PE TEOS film 106 is removed before the microlenses are formed. Also, if the microlenses 200 are formed when the metal pad 100 is exposed, image characteristics of the image sensor are only slightly deteriorated in comparison with the case that the PE TEOS film is etched after the microlenses are formed.

As shown in FIG. 9, the microlenses 202 are formed on the planarization layer 200. At this time, the microlenses 202 are formed when the metal pad 100 is exposed as the pad passivation film 106 is removed. In this case, the metal pad is not contaminated because an exposure is not successively performed.

As described above, the method for fabricating the CMOS image sensor according to the present invention has at least the following advantages.

Since the pad passivation film is formed thickly and uniformly, it is possible to improve white uniformity and prevent the yield of the image sensor from being deteriorated. Also, since the pad passivation film is etched before the microlenses are formed, it is possible to prevent the microlenses from being damaged, thereby improving image quality, including white uniformity, and also prevent the yield of the image sensor from being deteriorated.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method for fabricating a CMOS image sensor comprising:
forming a metal pad on a pad region of a semiconductor substrate having an active region and the pad region;
forming an insulating film on a surface of the semiconductor substrate, including the metal pad;
forming an opening to expose the metal pad by etching a portion of the insulating film corresponding to the metal pad;
forming a pad passivation film on the insulating film, including the opening;
forming color filter layers on a portion of the pad passivation film corresponding to the active region;
removing a portion of the pad passivation film corresponding to the pad region; and
forming microlenses over the color filter layers after removing the portion of the pad passivation film corresponding to the pad region.

2. The method as claimed in claim 1, further comprising forming a planarization layer between the color filter layers and the microlenses.

3. The method as claimed in claim 2, wherein the pad passivation film is removed using the planarization layer as a mask.

4. The method as claimed in claim 1, wherein the pad passivation film is formed at a thickness of about 800 Å to about 1200 Å.

5. The method as claimed in claim 1, wherein the step of forming the insulating film includes forming an oxide film on the entire surface of the semiconductor substrate, including the metal pad, and forming a nitride film on the oxide film.

6. The method as claimed in claim 1, further comprising performing a thermal curing process after forming the pad passivation film.

7. The method as claimed in claim 1, wherein the pad passivation film is removed by a plasma dry etching process.

8. The method as claimed in claim 1, wherein the pad passivation film includes a PE TEOS film.

9. The method as claimed in claim 5, wherein the oxide film includes a USG HDP film.

10. The method as claimed in claim 5, wherein the nitride film includes a PECVD SiN film.
